(19) United States
(12) Patent Application Publication
(10) Pub. No.: US 2015/0069856 A1
(43) Pub. Date: Mar. 12, 2015

(54) ELECTRONIC DEVICE MODULE, ELECTRONIC DEVICE THEREOF, PROTECTION ELEMENT THEREOF AND METHOD OF RAISING WORKING FREQUENCY THEREOF

(71) Applicant: WISTRON CORPORATION, NEW TAIPEI CITY (TW)

(72) Inventors: Ming-Chih Chen, New Taipei City (TW); Yung-Li Jang, New Taipei City (TW); Chun Wang, New Taipei City (TW)

(73) Assignee: WISTRON CORPORATION, NEW TAIPEI CITY (TW)

(21) Appl. No.: 14/188,780

(22) Filed: Feb. 25, 2014

(30) Foreign Application Priority Data
Sep. 12, 2013 (CN) 201310415374.5

(51) Int. Cl. H03K 17/95

(52) U.S. Cl. CPC H03K 17/95
USPC 307/116

(57) ABSTRACT

An electronic device module, an electronic device thereof, a protection element thereof and a method of raising working frequency thereof are provided. The electronic device module comprises the electronic device and the protection element. The electronic device comprises a main body, a device detection element and a central processing unit (CPU), wherein the device detection element and the CPU are disposed within the main body. The protection element comprises a protection cover and a protection detection element, wherein the protection detection element is disposed on the protection cover. The CPU raises a working frequency thereof according to an approaching movement between the device detection element and the protection detection element.

This application claims the benefit of People's Republic of China application Serial No. 201310415374.5, filed Sep. 12, 2013, the subject matter of which is incorporated herein by reference.

### BACKGROUND OF THE INVENTION

1. Field of the Invention

The invention relates in general to an electronic device module, an electronic device thereof, a protection element thereof and a method of raising working frequency thereof, and more particularly to an electronic device module with sensor, an electronic device thereof, a protection element thereof and a method of raising working frequency thereof.

2. Description of the Related Art

Conventional electronic device, such as a tablet PC, cannot be equipped with a fan for dissipating the heat due to the limitation of the space. Therefore, as long as the CPU of the tablet PC raises a working frequency thereof for a while, the tablet PC will generate extra heat and make the user's palm feel hot, not only causing nuisance to the user but also making it difficult to increase the working frequency of the CPU for the tablet PC.

### SUMMARY OF THE INVENTION

The invention is directed to an electronic device module, an electronic device thereof, a protection element thereof and a method of raising working frequency thereof for increasing a working frequency thereof.

According to one embodiment of the present invention, an electronic device module is provided. The electronic device module comprises an electronic device and a protection element. The electronic device comprises a main body, a device detection element and a central processing unit (CPU), wherein the device detection element and the CPU are disposed within the main body. The protection element comprises a protection cover and a protection cover detection element, wherein the protection cover detection element is disposed on the protection cover. The CPU raises a working frequency thereof according to an approaching movement between the device detection element and the protection cover detection element.

According to another embodiment of the present invention, an electronic device is provided. The electronic device comprises a main body, a device detection element and a CPU. The device detection element is disposed on the main body. The CPU is disposed within the main body. The CPU raises a working frequency thereof according to an approaching movement between the device detection element and the protection cover detection element.

According to an alternate embodiment of the present invention, a protection element is provided. The protection element comprises a protection cover and a protection cover detection element. The protection cover detection element is disposed on the protection cover. An electronic device comprises a main body, a CPU and a device detection element, wherein the CPU and the device detection element are disposed within the main body. The CPU raises a working frequency thereof according to an approaching movement between the device detection element and the protection cover detection element.

According to another alternate embodiment of the present invention, a method of raising working frequency is provided. The method of raising working frequency comprises following steps. An electronic device and a protection element are provided, wherein the electronic device comprises a main body, a device detection element and a central processing unit (CPU), the device detection element and the CPU are disposed within the main body, and the protection element comprises a protection cover and a protection cover detection element disposed on the protection cover. A working frequency thereof is raised by the CPU according to the protection cover detection element and the device detection element.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1A is an explosion diagram of an electronic device module according to an embodiment of the invention;

FIG. 1B is an assembly diagram of the electronic device module of FIG. 1A;

FIG. 2 is an explosion diagram of an electronic device module according to another embodiment of the invention; and

FIG. 3 is an explosion diagram of an electronic device module according to another embodiment of the invention

### DETAILED DESCRIPTION OF THE INVENTION

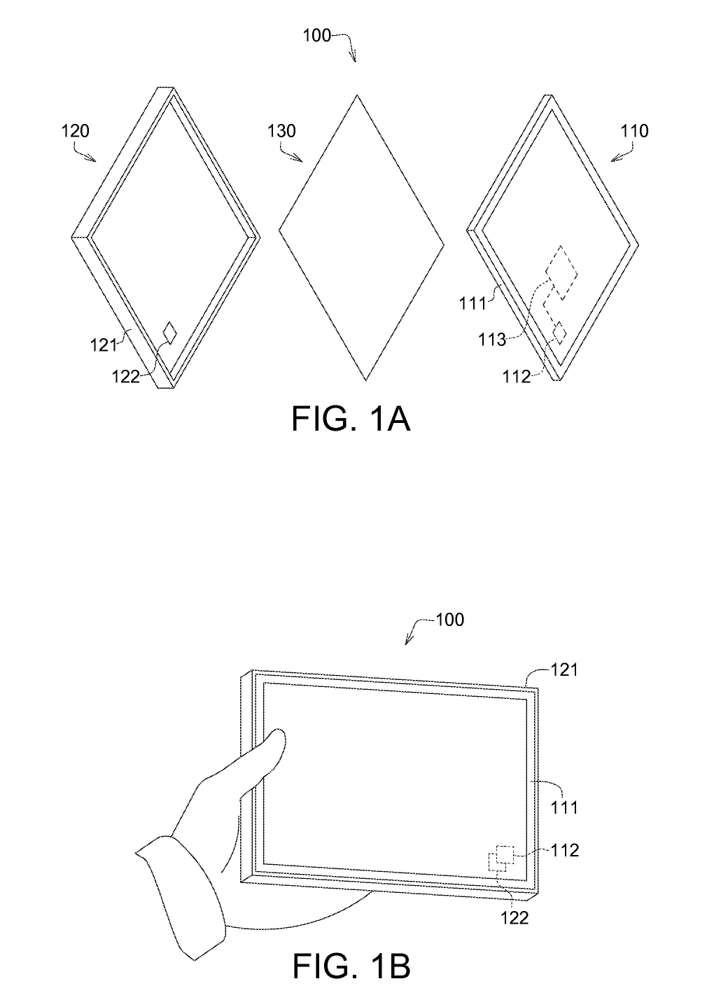

Referring to FIG. 1A, an explosion diagram of an electronic device module according to an embodiment of the invention is shown. The electronic device module 100 comprises an electronic device 110, an adhesive layer 130 and a protection element 120.

The electronic device 110 is such as a tablet PC, a mobile phone or a hand-held electronic device. The electronic device 110 comprises a main body 111, a device detection element 112 and a CPU 113, wherein the device detection element 112 and the CPU 113 are disposed within the main body 111. In the present embodiment, the device detection element 112 is a magnetic field sensor which can be disposed within the main body 111 or on an outer surface of the main body 111.

The protection element 120 comprises a protection cover 121 and a protection cover detection element 122. The adhesive layer 130 is such as a non-setting adhesive disposed between the main body 111 and the protection cover 121 for stabilizing relative positions between the main body 111 and the protection cover 121. In the present embodiment, the protection cover detection element 122 is a magnetic element such as a permanent magnet disposed within the protection cover 121 or on an outer surface of the protection cover 121. The protection cover 121 and the main body 111 can be combined together to avoid the main body 111 being worn and torn or to absorb the impact received by the main body 111 when falling to the ground and avoid the main body 111 being severely damaged.

Referring to FIG. 1B, an assembly diagram of the electronic device module of FIG. 1A is shown. The protection cover 121 is formed by such as a thermal insulating material. The thermal barrier provided by the protection cover 121 impedes the main body 111 conducting the heat to the user's palm so that the user's palm will not feel hot. For instance, in a method of raising a working frequency of an electronic device, when the protection cover 121 and the main body 111 are combined together, the device detection element 112 and the protection cover detection element 122 will approach each other and generate electromagnetic induction, so that the CPU 113 of the electronic device 110 raises a working frequency thereof according to the electromagnetic induction. By doing so, the CPU 113 will generate extra heat, but the user's palm does not feel hot due to the thermal barrier of the protection cover 121. Here, “approach” refers to “get close but not directly contact” or “directly contact”. In another embodiment, when the device detection element 112 and the protection cover detection element 122 are separated from each other, the CPU 113 reduces a working frequency thereof according to a departing movement between the device detection element 112 and the protection cover detection element 122.

The CPU 113 may raise a working frequency thereof according to an electromagnetic induction between the device detection element 112 and the protection cover detection element 122 as well as a mechanical detection exemplified below.

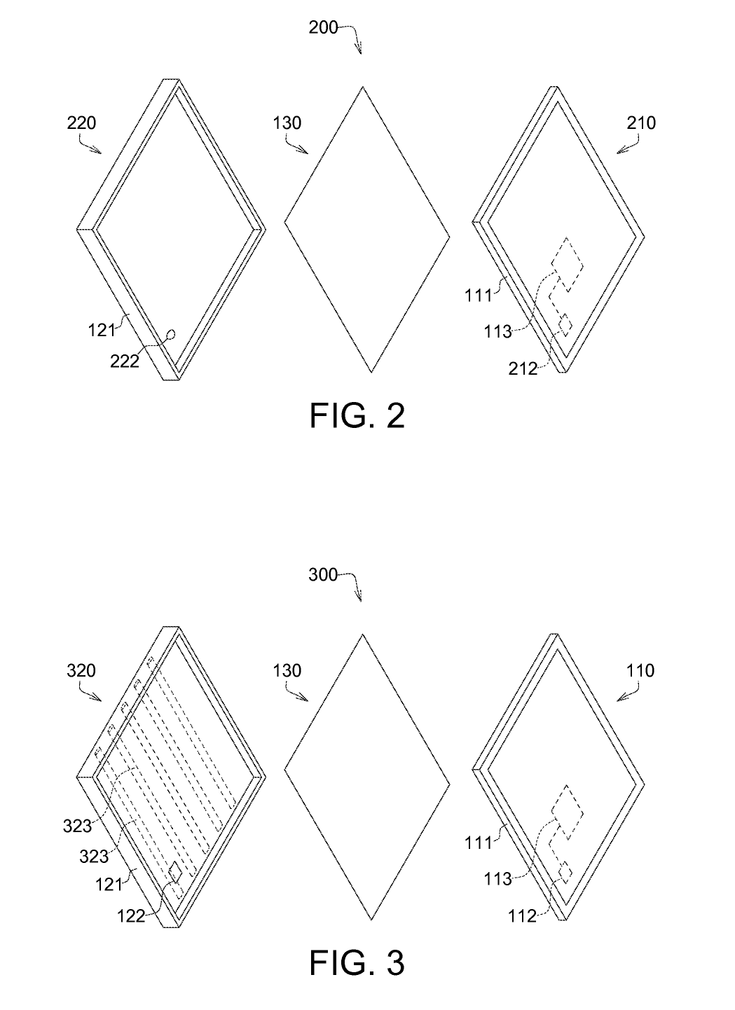

Referring to FIG. 2, an explosion diagram of an electronic device module according to another embodiment of the invention is shown. The electronic device module 200 comprises an electronic device 210, an adhesive layer 130 and a protection element 220.

The electronic device 210 is such as a tablet PC, a mobile phone or a hand-held electronic device. The electronic device 210 comprises a main body 111, a device detection element 212 and a CPU 113, wherein the device detection element 212 and the CPU 113 are disposed within the main body 111. In the present embodiment, the device detection element 212 is such as a mechanical button disposed on an outer surface of the main body 111.

The protection element 220 comprises a protection cover 121 and a protection cover detection element 222, wherein the protection cover detection element 222 is such as a protruding portion which cooperates with the device detection element 212. The protruding portion is protruded from an outer surface of the protection cover 121 for triggering the device detection element 212.

The position of the device detection element 112 corresponds to that of the protection cover detection element 122. Therefore, when the protection cover 121 and the main body 111 are combined together, the protection cover detection element 122 triggers the device detection element 112, and the CPU 113 raises a working frequency thereof accordingly. Although the CPU 113 generates extra heat, the heat is blocked by the protection cover 121 and the user's palm will not feel hot.

Referring to FIG. 3, an explosion diagram of an electronic device module according to another embodiment of the invention is shown. The electronic device module 300 comprises an electronic device 110, an adhesive layer 130 and a protection element 320. The electronic device 110 comprises a main body 111, a device detection element 112 and a CPU 113, wherein the device detection element 112 and the CPU 113 are disposed within the main body 111. The protection element 320 comprises a protection cover 121, a protection cover detection element 122 and a thermal conductive element 323, wherein the protection cover detection element 122 and the thermal conductive element 323 are disposed on the protection cover 121. The thermal conductive element 323, such as a heat pipe, is disposed within the protection cover 121 for quickly conducting the heat to the outside of the electronic device 110. When the protection cover 121 and the main body 111 are combined together, the CPU 113 raises a working frequency thereof according to an approaching movement between the protection cover detection element 122 and the device detection element 112. By doing so, the CPU 113 will generate extra heat. However, the thermal conductive element 323 is capable of conducting the heat to the outside of the electronic device 110, and the palm will not feel too hot.

In an embodiment, the electronic device 110 of the electronic device module 300 can be replaced by the electronic device 210. In another embodiment, the protection cover 121 of the electronic device module 300 can be formed by a thermal insulating material. Under such design, the electronic device module 300 can selectively omit the thermal conductive element 323.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. An electronic device module, comprising:
an electronic device, comprising a main body, a device detection element and a central processing unit (CPU), wherein the device detection element and the CPU are disposed within the main body; and
a protection element, comprising a protection cover and a protection cover detection element, wherein the protection cover detection element is disposed on the protection cover;
wherein, the CPU raises a working frequency thereof according to an approaching movement between the device detection element and the protection cover detection element.

2. The electronic device module according to claim 1, wherein the CPU reduces a working frequency thereof according to a departing movement between the device detection element and the protection cover detection element.

3. The electronic device module according to claim 1, wherein the main body is a tablet PC or a mobile phone.

4. The electronic device module according to claim 1, wherein the device detection element is a magnetic field sensor, and the protection cover detection element is a magnetic element.

5. The electronic device module according to claim 1, wherein the device detection element and the protection cover detection element are two mechanical triggering elements cooperating with each other.

6. The electronic device module according to claim 1, further comprising:
an adhesive layer disposed between the main body and the protection cover.

7. The electronic device module according to claim 1, wherein the protection cover is formed by a thermal insulating material.

8. The electronic device module according to claim 1, wherein the protection cover is formed by a thermal conductive material.

9. The electronic device module according to claim 1, wherein the protection element further comprises:
a thermal conductive element disposed within the protection cover for conducting the heat of the main body to the outside of the protection cover.

10. An electronic device, comprising:
a main body;
a device detection element disposed on the main body; and
a CPU disposed within the main body;
wherein, the CPU raises a working frequency thereof according to an approaching movement between the device detection element and a protection cover detection element.

11. The electronic device according to claim 10, wherein the main body is a tablet PC or a mobile phone.

12. The electronic device according to claim 10, wherein the device detection element is a magnetic field sensor, and the protection cover detection element is a magnetic element.

13. The electronic device according to claim 10, wherein the device detection element and the protection cover detection element are two mechanical triggering elements cooperating with each other.

14. A protection element, comprising:
a protection cover; and
a protection cover detection element disposed on the protection cover;
wherein, an electronic device comprises a main body, a CPU and a device detection element, the CPU and the device detection element are disposed within the main body, and the CPU raises a working frequency thereof according to an approaching movement between the device detection element and the protection cover detection element.

15. The protection element according to claim 14, wherein the device detection element is a magnetic field sensor, and the protection cover detection element is a magnetic element.

16. The protection element according to claim 14, wherein the device detection element and the protection cover detection element are two mechanical triggering elements cooperating with each other.

17. The protection element according to claim 14, wherein the protection cover is formed by a thermal insulating material.

18. The protection element according to claim 14, wherein the protection cover is formed by a thermal conductive material.

19. The protection element according to claim 14, wherein the protection element further comprises:
a thermal conductive element disposed within the protection cover for conducting the heat of the main body to the outside of the protection cover.

20. A method of raising working frequency, comprising:
providing an electronic device and a protection element, wherein the electronic device comprises a main body, a device detection element and a CPU, the device detection element and the CPU are disposed within the main body, and the protection element comprises a protection cover and a protection cover detection element disposed on the protection cover; and
raising a working frequency by the CPU according to the protection cover detection element and the device detection element.

21. The method of raising working frequency according to claim 20, wherein the CPU reduces a working frequency thereof according to a departing movement between the device detection element and the protection cover detection element.
